(19) United States
(12) Patent Application Publication
(10) Pub. No.: US 2010/0060770 A1
(43) Pub. Date: Mar. 11, 2010

(54) SOLID-STATE IMAGING DEVICE AND IMAGING APPARATUS

(75) Inventor: Makoto SIZUKUISI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/557,990

(22) Filed: Sep. 11, 2009

(30) Foreign Application Priority Data
Sep. 11, 2008 (JP) P2008-233565

(51) Int. Cl. H04N 5/335

(52) U.S. Cl. 348/311; 348/E05.091

(57) ABSTRACT

A solid-state imaging device 1 includes a photoelectric conversion section 17 and a writing transistor 18. The photoelectric conversion section 17 is provided in a semiconductor substrate. The writing transistor 18 has a floating gate 16 and a control gate 15. The floating gate 16 is provided above the semiconductor substrate. The control gate 15 injects electric charges generated in the photoelectric conversion section 17 into the floating gate 16. The control gate 15 is provided in a position that does not overlap with the photoelectric conversion section 17 in plan view, and is provided so as to be brought into contact with all sides of the peripheral edge of the photoelectric conversion section 17.

### CROSS-REFERENCE TO RELATED APPLICATIONS

This application claims the benefit of Japanese Patent Application No. 2008-233565, filed Sep. 11, 2008, the entire contents of which are hereby incorporated by reference, the same as if set forth at length.

### BACKGROUND OF THE INVENTION

1. Technical Field

The present invention relates to a solid-state imaging device including (i) a photoelectric conversion section provided in a semiconductor substrate and (ii) a writing transistor having an electric charge accumulation section provided above the semiconductor substrate and a control gate that injects electric charges generated in the photoelectric conversion section into the electric charge accumulation section. The present invention also relates to an imaging apparatus including the solid-state imaging device.

2. Related Art

JP 2002-280537 A has proposed a solid-state imaging apparatus in which a MOS transistor with a floating gate (FG) serving as an electric charge accumulation section injects and records, into the FG, electric charges generated in a photoelectric conversion element such as a photodiode (PD), and a signal corresponding to the electric charges recorded in the FG is read to outside, thereby taking an image.

Such a solid-state imaging apparatus is required the followings:
To guide incident light to the photoelectric conversion element without loss of the incident light (i.e., to improve incident light utilization efficiency);
To inject the electric charges generated in the photoelectric conversion element into the FG with a high probability (i.e., to improve electric charge injection efficiency); and
To inject the electric charges generated in the photoelectric conversion element into the FG at a high speed (i.e., to increase an electric charge injection speed).

In the solid-state imaging apparatus described in JP 2002-280537 A, a control gate CG of a writing memory element WM is in close proximity to only a part of the PD, and a region, through which the electric charges generated in the PD flows out from the PD, is limited to the part of the PD. Therefore, there has been a demand for a structure capable of further improving the efficiency of electric charge injection from the PD to the FG.

JP 2001-85660 A (corresponding to U.S. Pat. No. 6,784,933) describes a structure in which a FG and a control gate are provided so as to be overlapped with a PD, and electric charges generated in the PD by incident light which transmits through the FG and the control gate are injected into the FG. In this structure, a region through which the electric charges from the PD flows out corresponds to a portion at which the PD surface and the control gate are overlapped. Therefore, the electric charge injection efficiency can be improved if the control gate is enlarged. However, in this structure, the FG and the control gate considerably inhibit short-wavelength light (e.g., blue light) from entering thereinto in particular, but allow long-wavelength light (e.g., red light) to transmit therethrough, thereby causing unbalanced color reproduction (white balance). Furthermore, depending on an angle of incident light, the vignetting amount due to the FG and the control gate significantly changes, which becomes the cause of brightness and color shading.

### SUMMARY

The present invention has been made in view of the above circumstances, and provides a solid-state imaging device capable of enhancing incident light utilization efficiency, electric charge injection efficiency and electric charge injection speed with a simple structure, and an imaging apparatus having the solid-state imaging device.
[1] According to an aspect of the invention, a solid-state imaging device includes a photoelectric conversion section and a writing transistor. The photoelectric conversion section is provided in a semiconductor substrate. The writing transistor includes an electric charge accumulation section and a control gate. The electric charge accumulation section is provided above the semiconductor substrate. The control gate injects electric charges generated in the photoelectric conversion section into the electric charge accumulation section. The control gate is located outside of a region, onto which light is incident, of the photoelectric conversion section in plan view. The control gate is overlapped with at least two sides of a peripheral edge of the photoelectric conversion section in plan view.

With this configuration, the control gate is provided outside of the region, onto which light is incident, of the photoelectric conversion section. Therefore, if the electric charge accumulation section is located so as to be completely overlapped with the control gate, for example, it becomes possible to allow the incident light to be incident onto the photoelectric conversion section without the incident light being blocked by the electric charge accumulation section and the control gate. As a result, degradation in light utilization efficiency can be prevented. Also, the control gate is overlapped with two or more of the sides constituting the peripheral edge of the photoelectric conversion section. Therefore, the region, through which the electric charges generated in the photoelectric conversion section flows out from the photoelectric conversion section, is enlarged (i.e., electric charge injection cross-sectional area can be increased). Accordingly, the efficiency of electric charge injection into the electric charge accumulation section can be improved, and the speed of electric charge injection into the electric charge accumulation section can be increased.
[2] In the solid-state imaging device of [1], the control gate may be overlapped with all sides of the peripheral edge of the photoelectric conversion section in plan view.

With this configuration, the entire peripheral edge of the photoelectric conversion section can serve as the region through which the electric charges generated in the photoelectric conversion section flows out from the photoelectric conversion section. Accordingly, the electric charge injection efficiency and the electric charge injection speed can be enhanced to the maximum extent possible.
[3] The solid-state imaging device of any one of [1] to [2] may further include a reading transistor. The reading transistor reads a signal corresponding to the electric charges injected into the electric charge accumulation section. The writing transistor may have a two-terminal structure having a source connected to the photoelectric conversion section and the control gate.

With this configuration, since no drain region of the writing transistor exists in the vicinity of the electric charge accumulation section, injection of a dark current from a drain region can be prevented. Also, since the efficiency of electric charge injection and suppression of a dark current can be simultaneously realized in this manner, the S/N ratio can be improved. In particular, in the above-described solid-state imaging device, the control gate is in contact with the two or more sides of the peripheral edge of the photoelectric conversion section. Therefore, if an attempt were to be made to provide a drain region for the writing transistor, the drain region would be provided to be opposed to the two or more sides of the peripheral edge of the photoelectric conversion section, and the dark current injected from this drain region would be increased, which might degrade the S/N ratio. With the above described configuration, such a drain region does not exist, and therefore, the dark current can be suppressed.
[4] In the solid-state imaging device of [4], the photoelectric conversion section may be formed of a first impurity layer of a first conductivity type. The solid-state imaging device may further include a second impurity layer that is formed at a surface of the first impurity layer of the first conductivity type and that has a second conductivity type opposite to the first conductivity type. A part of the second impurity layer may extend to a region above a device isolation region having the second conductivity type and may be connected to the device isolation region. One part of the electric charge accumulation section located above the part of the second impurity layer and the other parts of the electric charge accumulation section may be formed above the semiconductor substrate via insulating films having different thicknesses. The insulating film located between the one part of the electric charge accumulation section located above the part of the second impurity layer and the semiconductor substrate may be thicker than the insulating film located between the other parts of the electric charge accumulation section and the semiconductor substrate.
[5] According to another aspect of the invention, an imaging apparatus includes the solid-state imaging device of any one of [1] to [4].

With any of the above configurations, a solid-state imaging device capable of enhancing incident light utilization efficiency, electric charge injection efficiency and electric charge injection speed can be achieved with a simple structure.

### BRIEF DESCRIPTION OF THE DRAWINGS

FIG. 1A is a schematic diagram illustrating a schematic configuration of a solid-state imaging device, for describing an embodiment of the present invention.

FIG. 1B is a diagram illustrating an example of a reading circuit.

FIG. 2 is a schematic plan view illustrating a schematic configuration of a pixel portion illustrated in FIG. 1 and a periphery of the pixel portion.

FIG. 3 is a diagram in which reading control lines 10 and writing control lines 11 illustrated in FIG. 2 are omitted.

FIG. 4 is an equivalent circuit diagram of the pixel portion illustrated in FIG. 1.

FIG. 5 is a schematic section view taken along a line A-A′ of FIG. 2.

FIG. 6 is a schematic section view taken along a line B-B′ of FIG. 2.

FIG. 7 is a schematic section view taken along a line C-C′ of FIG. 2.

FIG. 8 is a schematic section view taken along a line D-D′ of FIG. 2.

FIG. 9 is a schematic section view taken along a line E-E′ of FIG. 2.

FIG. 10A is a diagram illustrating a modified example of a control gate.

FIG. 10B is a diagram illustrating another modified example of the control gate.

### DETAILED DESCRIPTION OF EMBODIMENTS OF THE INVENTION

Hereinafter, a solid-state imaging device according to embodiments of the present invention will be described with reference to the accompanying drawings. This solid-state imaging device may be incorporated into an imaging apparatus such as a digital still camera or a digital video camera, for use.

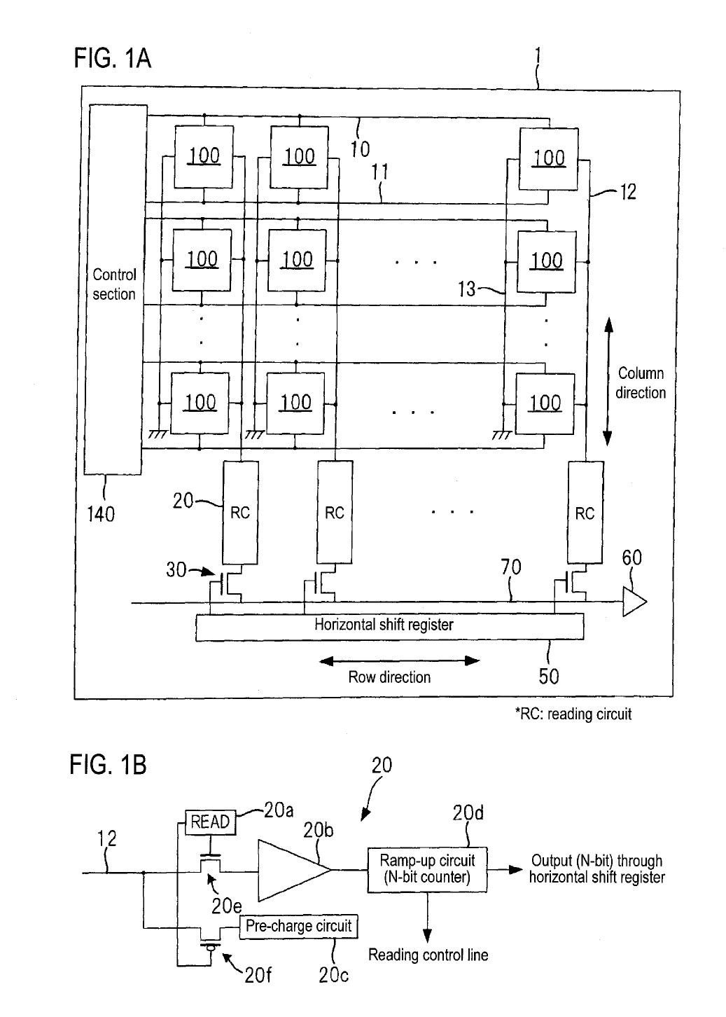

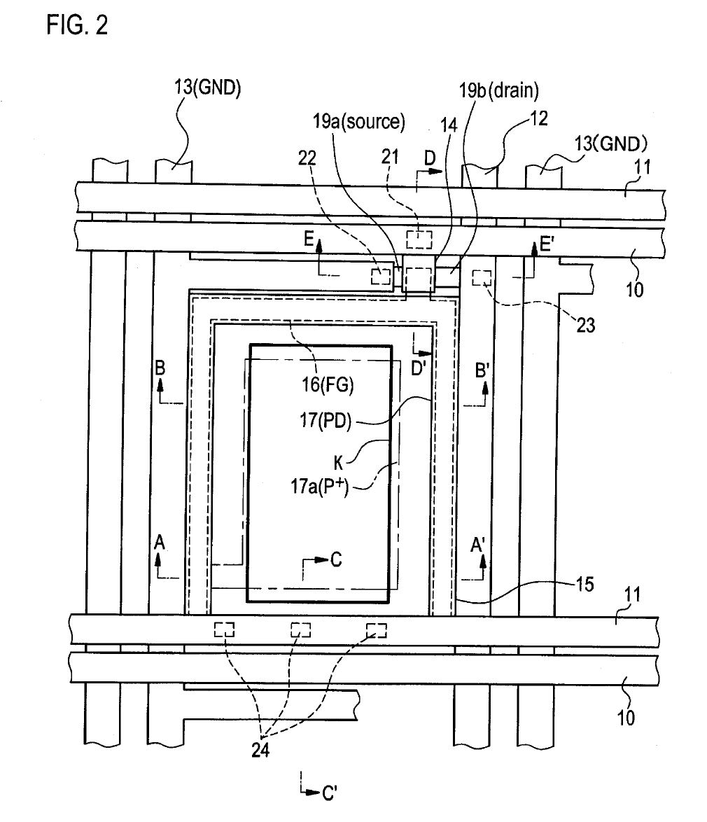

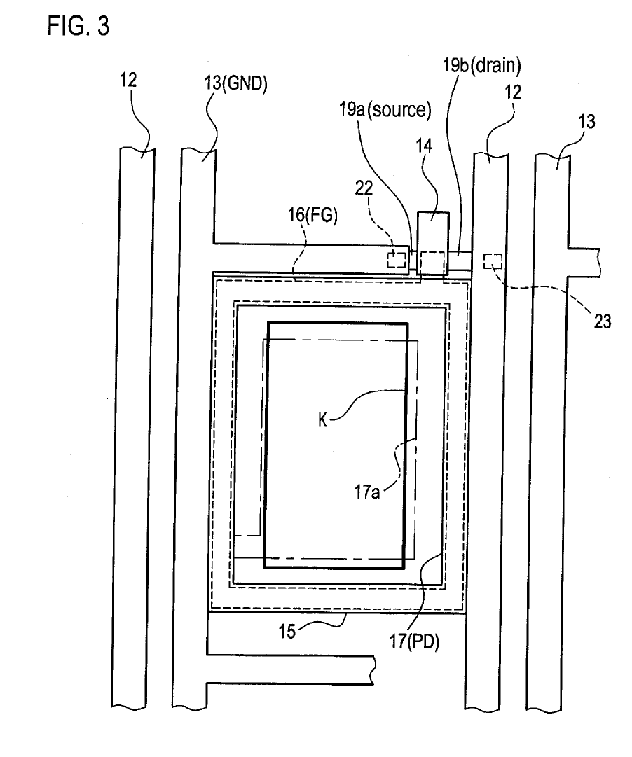

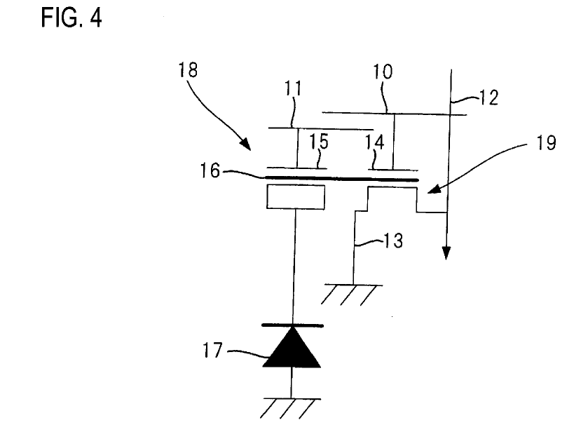

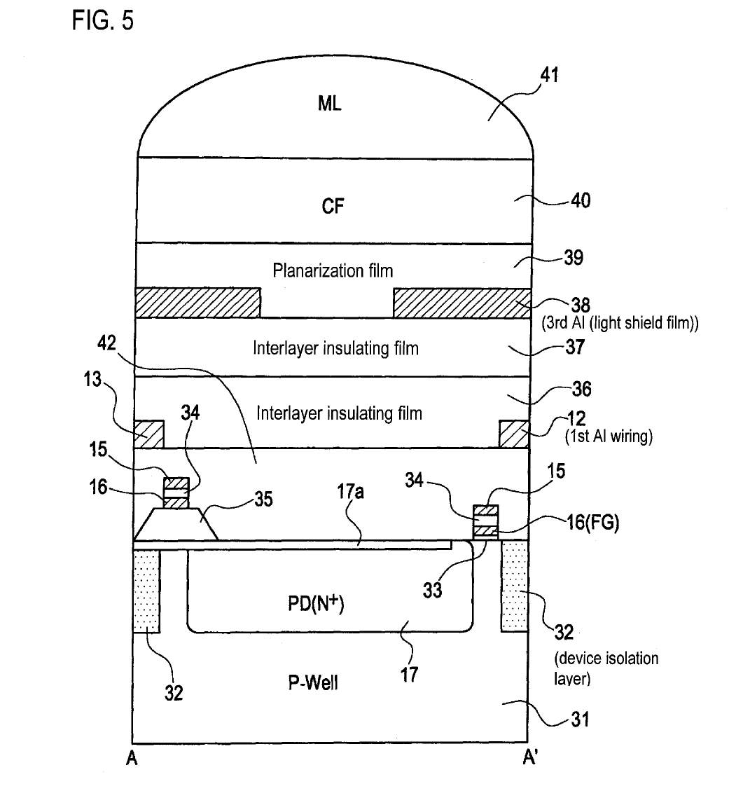

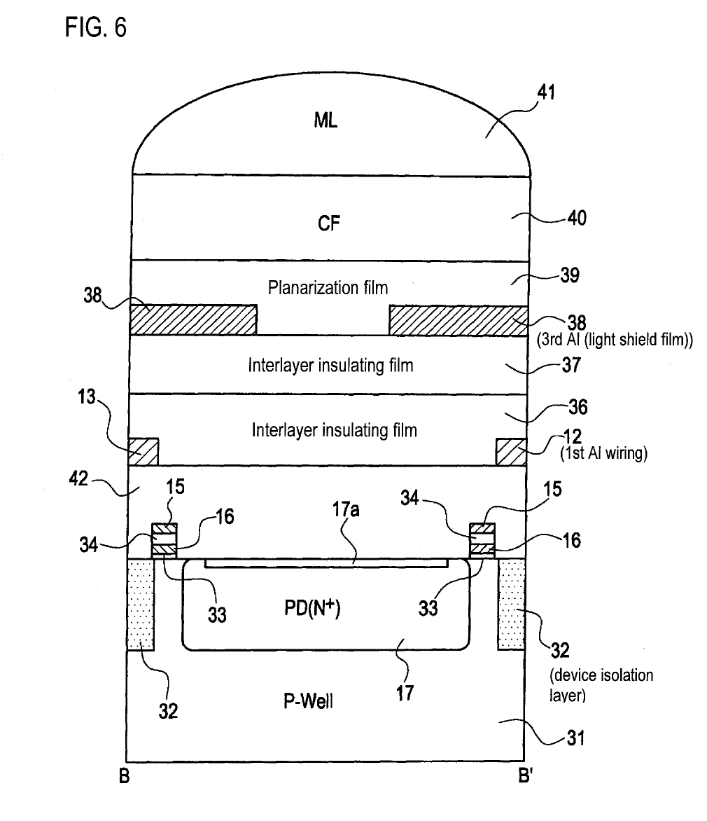

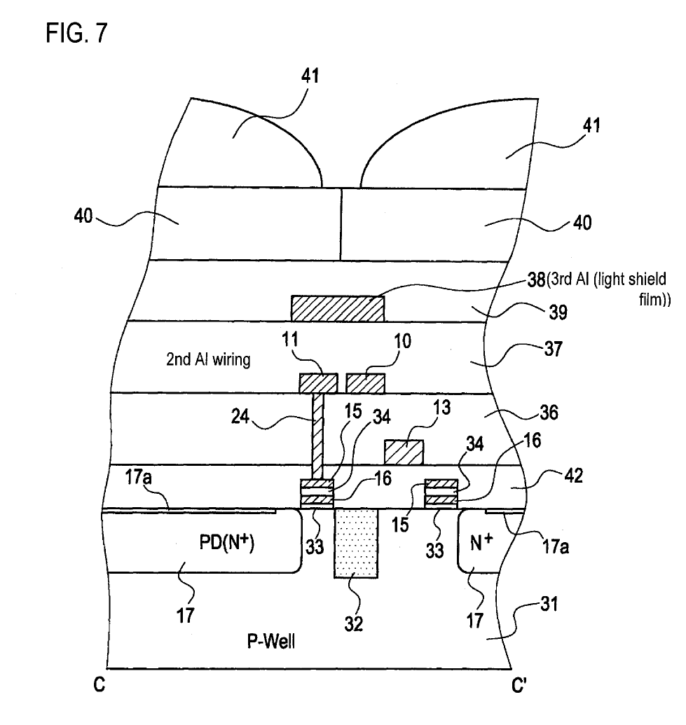

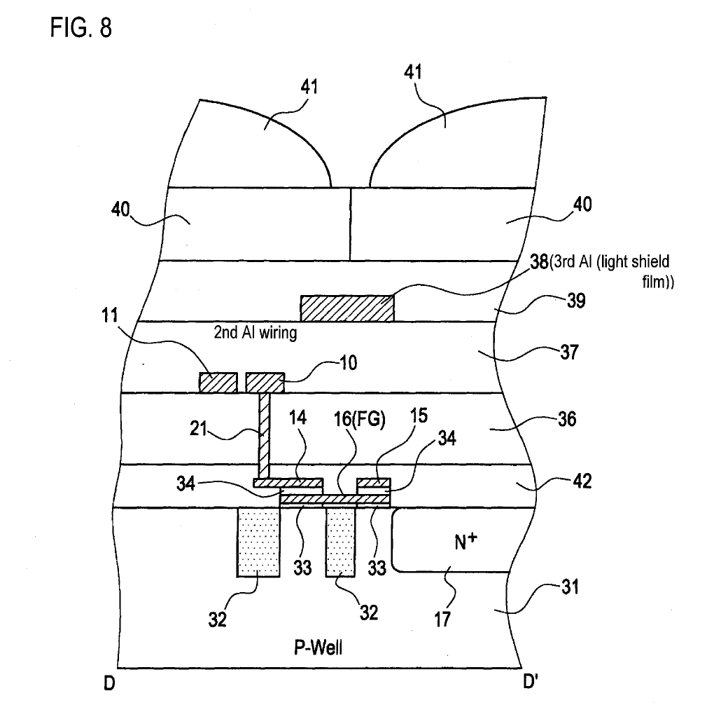

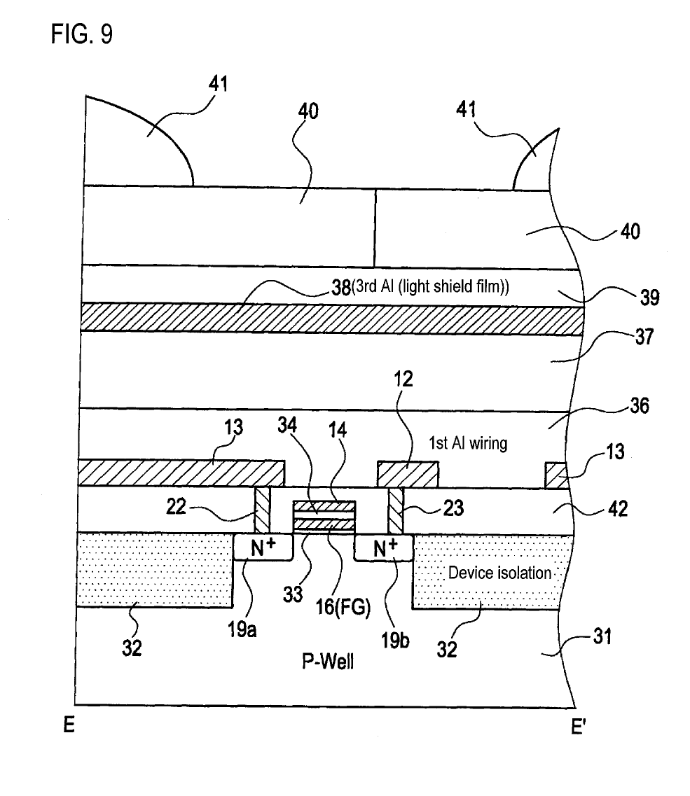

FIG. 1A is a schematic diagram illustrating a schematic configuration of the solid-state imaging device, for describing one embodiment of the present invention. FIG. 1B is a diagram illustrating an example of a reading circuit. FIG. 2 is a schematic plan view illustrating a schematic configuration of a pixel portion illustrated in FIG. 1 and a periphery of the pixel portion. FIG. 3 is a diagram in which reading control lines 10 and writing control lines 11 illustrated in FIG. 2 are omitted. FIG. 4 is an equivalent circuit diagram of the pixel portion illustrated in FIG. 1. FIG. 5 is a schematic section view taken along a line A-A′ of FIG. 2. FIG. 6 is a schematic section view taken along a line B-B′ of FIG. 2. FIG. 7 is a schematic section view taken along a line C-C′ of FIG. 2. FIG. 8 is a schematic section view taken along a line D-D′ of FIG. 2. FIG. 9 is a schematic section view taken along a line E-E′ of FIG. 2.

The solid-state imaging device 1 includes a large number of pixel portions 100 arranged in an array pattern (a square grid pattern in this embodiment) in a row direction and in a column direction perpendicular to the row direction on the same plane.

The pixel portions 100 each includes a photoelectric conversion section 17 such as a pn junction photodiode (PD) formed in a semiconductor substrate. As illustrated in FIG. 3, the photoelectric conversion section 17 has a rectangular shape. However, the shape of the photoelectric conversion section 17 is not limited thereto, so long as the photoelectric conversion section 17 has a polygonal shape having three or more sides. A circle or an ellipse having an infinite number of sides may also be referred to as a polygon. As illustrated in FIGS. 5 and 6, the photoelectric conversion section 17 is an n-type impurity layer formed on an inner side of a surface of a p well layer 31 formed in the semiconductor substrate (which is an n-type silicon substrate in this embodiment). A photodiode is constituted by a pn junction between the p well layer 31 and the photoelectric conversion section 17.

The pixel portions 100 are each provided with a signal reading circuit capable of reading, to the outside, a signal corresponding to electric charges generated in the photoelectric conversion section 17. As illustrated in FIG. 4, the signal reading circuit includes a writing transistor (hereinafter, “WT”) 18 and a reading transistor (hereinafter, “RT”) 19. The writing transistor 18 is configured to record the electric charges generated in the photoelectric conversion section 17. The reading transistor 19 is configured to read a signal corresponding to the recorded electric charges.

Above the p well layer 31, a control gate 15 of the WT 18 is formed so as to surround the photoelectric conversion section 17 in plan view. The control gate 15 is an electrode formed of a conductive material such as polysilicon. As illustrated in FIG. 3, the control gate 15 is formed into such a shape that an opening having approximately the same shape as the photoelectric conversion section 17 is formed in the rectangular electrode.

It should be noted that in the figures, the peripheral edge of the above-mentioned opening and that of the photoelectric conversion section 17 perfectly coincide with each other, but actually, these peripheral edges do not perfectly coincide with each other. This is because, for example, when the control gate 15 is formed and then the photoelectric conversion section 17 is formed in a self-aligned manner by implanting an impurity ion into the p well layer 31 using the control gate 15 as a mask, the impurity ion of the photoelectric conversion section 17 is also thermally diffused laterally due to a subsequent thermal process. In other words, the control gate 15 is formed so as to be overlapped with the peripheral edge of the photoelectric conversion section 17.

Also, in order to increase the efficiency of light incidence onto the photoelectric conversion section 17, the control gate 15 is located outside of a region K, onto which light is incident, of the photoelectric conversion section 17 (i.e., a region which is determined in advance by an opening formed in a light shield film 38 that is provided above the photoelectric conversion section 17).

As illustrated in FIGS. 3 and 9, in the vicinity of the photoelectric conversion section 17 within the p well layer 31, there are formed a source region 19a and a drain region 19b of the RT 19, which are formed of a high concentration n-type impurity layer, and there is provided a control gate 14 of the RT 19 above a region of the p well layer 31, located between these source region 19a and drain region 19b. The control gate 14 is an electrode made of a conductive material such as polysilicon.

Between the control gate 15 and the p well layer 31, there is provided a floating gate (hereinafter, “FG”) 16 made of a conductive material such as electrically floating polysilicon. The FG 16 is formed into a shape approximately the same as that of the control gate 15 (FIGS. 2 and 3 illustrate the FG 16 so that its width is narrower than the width of the control gate 15 in order to facilitate visualization), and is located so as to be substantially overlapped with the control gate 15 in plan view. As illustrated in FIGS. 2, 3 and 8, the FG 16 has a convex portion, in plan view, extending from a region opposed to the control gate 15 to a region below the control gate 14. With this configuration, a shared FG structure in which the FG 16 is shared between the WT 18 and the RT 19 is realized. It should be noted that the FG 16 may have a width narrower or wider than that of the control gate 15, and may be partially overlapped with the control gate 15.

In order to realize dark current reduction and/or complete depletion, a p-type impurity layer 17a is provided on the surface of the photoelectric conversion section 17. The p-type impurity layer 17a is formed inside of the peripheral edge of the photoelectric conversion section 17 in plan view. A part of the p-type impurity layer 17a projects to an outside of the peripheral edge of the photoelectric conversion section 17. The part of the p-type impurity layer 17a projected from the photoelectric conversion section 17 is connected to a device isolation region 32 formed of a p-type impurity layer formed in the p well layer 31, thereby fixing the p-type impurity layer 17a to the ground.

The inside of the p well layer 31 is classified into an active region and a device isolation region. The active region is a region where there exist the photoelectric conversion section 17, the p-type impurity layer 17a, the source region 19a, the drain region 19b, a channel region of the RT 19, and a channel region of the WT 18 (region overlapped with the control gate 15), while a region other than the active region may serve as the device isolation region.

Applicable device isolation methods include the LOCOS (Local Oxidation of Silicon) method, the STI (Shallow Trench Isolation) method, and a method that utilizes high concentration impurity ion implantation. In the illustrated example, the device isolation region 32 is formed by ion implantation of high concentration p-type impurity into the p well layer 31.

As illustrated in FIG. 5, a thick oxide film 35 is formed on the projected part of the p-type impurity layer 17a by a CVD process or the like, and the FG 16 and the control gate 15 are formed on/above this oxide film 35.

Between a part of the FG 16 other than its part located on the oxide film 35 and the p well layer 31, an oxide film 33 such as silicon oxide is formed. The oxide film 35 is thicker than the oxide film 33. Between the FG 16 and the control gates 15 and 14, an insulating film 34 such as an oxide film or a nitride film is formed. The control gates 14 and 15, the FG 16, the oxide film 33, the insulating film 34 and the oxide film 35 are embedded in an insulating film 42.

The WT 18 includes the control gate 15, the photoelectric conversion section 17 functioning as source and drain regions, and the FG 16. When the WT 18 is shown as an equivalent circuit, the WT 18 is provided as a MOS transistor having a two-terminal structure in which the source (which also serves as the drain) is connected to the photoelectric conversion section 17 as illustrated in FIG. 4. Examples of two-terminal devices include a resistor, a coil, a capacitor, and a diode, but an active device such as one that performs switching or signal amplification does not exist as a two-terminal device.

It was commonly understood that a transistor, which is an active device for performing pixel selection, reset, signal recording, reading and the like in a general solid-state imaging device, did not function with two terminals, and no one has tried to use such a transistor having the two-terminal structure.

In the structure of the solid-state imaging device of this embodiment, the FG 16 is shared between the WT 18 and the RT 19. Therefore, single operation of writing (i.e., electric charge injection and recording to the FG 16) and electric charge transfer in a single direction are solely required for the WT 18. At the time of signal reading, the signal reading can be performed also by the adjacent RT 19 using the above-described shared FG structure. Therefore, the inventor found that there is no operational problem whatsoever even if the WT 18 has the two-terminal structure.

Thus, this embodiment simplifies the configuration of the solid-state imaging device 1 by providing the WT 18 with the two-terminal structure.

The WT 18 applies a writing control voltage (WCG) of 7 V to 15 V, for example, to the control gate 15, thereby allowing the electric charges generated in the photoelectric conversion section 17 to be injected and recorded into the FG 16.

The RT 19 is a MOS transistor having a three-terminal structure. The RT 19 includes the FG 16, the source region 19a, the drain region 19b, and the control gate 14. The RT 19 applies a reading control voltage (RCG), which is increased in a continuous or stepwise manner, to the control gate 14 with a drain voltage of 3.3 V, for example, being applied to the drain region 19b, and detects a value of the RCG (=threshold voltage of the RT 19) when the channel region of the RT 19 is brought into conduction, thereby allowing the detected RCG value to be read out as an imaging signal corresponding to the electric charges accumulated in the FG 16.

The solid-state imaging device 1 includes a control section 140, reading circuits 20, a horizontal shift register 50 and an output amplifier 60. The control section 140 controls the WT 18 and the RT 19. Each of the reading circuits 20 detects the threshold voltages of the RTs 19. The horizontal shift register 50 carries out control so that the threshold voltages detected by the reading circuits 20 for each line are sequentially read as imaging signals to a signal line 70. The output amplifier 60 is connected to the signal line 70.

The reading circuits 20 are provided so as to be associated with respective columns constituted by a plurality of pixel portions 100 which are arranged in the column direction. The reading circuits 20 are each connected via a signal output line 12 to the drain regions 19b of the respective pixel portions 100 in the associated column. Furthermore, the reading circuits 20 are also connected to the control section 140.

The reading circuit 20 applies a drain voltage to the drain regions 19b of the RT 19, for example, while applying the reading control voltage RCG to the control gate 14 of the RT 19 via the control section 140, and detects, based on an electric current value of the drain region 19b with respect to the resultant electric potential of the control gate 14, a threshold voltage Vth of the RT 19.

Furthermore, in another example, as illustrated in FIG. 1B, each of the reading circuits 20 is configured to have a reading control section 20a, a sense amplifier 20b, a pre-charge circuit 20c, a ramp-up circuit 20d, and transistors 20e and 20f.

When a signal is to be read out from the pixel portion 100, the reading control section 20a turns on the transistor 20f, thereby supplying (pre-charging) from the pre-charge circuit 20c a drain voltage to the drain region 19b of the pixel portion 100 via the signal output line 12. Subsequently, the reading control section 20a turns on the transistor 20e, thereby bringing the drain region 19b of the pixel portion 100 and the sense amplifier 20b into conduction.

The sense amplifier 20b monitors a voltage of the drain region 19b of the pixel portion 100, detects a change in this voltage, and notifies the ramp-up circuit 20d of this change. For example, when a drop in the drain voltage pre-charged by the pre-charge circuit 20c is detected, the sense amplifier output is inverted.

The ramp-up circuit 20d contains an N-bit counter, supplies a ramp waveform voltage (RCG), which gradually increases or gradually decreases, to the control gate 14 of the pixel portion 100 via the control section 140, and outputs a count value (i.e., a binary value of N digits (a combination of N pieces of 1 and 0)) corresponding to the value of the ramp waveform voltage.

When the voltage of the control gate 14 exceeds the threshold voltage of the RT 19, the RT 19 is brought into conduction, and at this time, the electric potential of the column signal line 12, which is pre-charged, drops. This drop is detected by the sense amplifier 20b, and an inversion signal is output. Upon receipt of this inversion signal, the ramp-up circuit 20d retains (latches) the count value corresponding to the value of the ramp waveform voltage. Thus, a change in voltage (imaging signal) can be read out as a digital value (a combination of 1 and 0).

When the horizontal shift register 50 selects one of the horizontal selection transistors 30, the count value retained by the ramp-up circuit 20d connected to the selected horizontal selection transistor 30 is output to the signal line 70, and this count value is output as an imaging signal from the output amplifier 60.

The control section 140 is connected via the writing control line 11 to the control gate 15 of each pixel portion 100 of a line including the plural pixel portions 100, which are arranged in the row direction, and applies the writing control voltage WCG to the control gate 15 of each pixel portion 100, thereby carrying out control to accumulate in the FG 16 the electric charges generated in each photoelectric conversion section 17. Furthermore, the control section 140 is connected via the reading control line 10 to the control gate 14 of each pixel portion 100 of each line, and applies the reading control voltage RCG, which is supplied from the ramp-up circuit 20d, to the control gates 14 of the RTs 19 for each line independently. The control section 140 also carries out electric charge erasing control for collectively erasing the electric charges accumulated in the FG 16 of each pixel portion 100. The writing control voltage WCG may be generated by increasing a power supply voltage by a charge pump circuit (not shown).

Examples of the electric charge erasing method include a method for applying a negative voltage to the control gates 14 and 15 and for applying a positive voltage to the semiconductor substrate, thereby extracting the electric charges in the FG 16 to the inside of the semiconductor substrate.

As illustrated in FIG. 2, each writing control line 11 is disposed along lower-side regions of the pixel portions 100. Each wiring control line 11 is disposed so that a part of each writing control line 11 is overlapped with lower-side portions of the control gates 15 of the pixel portions 100. As illustrated in FIG. 7, the writing control line 11 is formed on an interlayer insulating film 36 formed on the insulating film 42, and is electrically connected to the control gate 15 via a plug 24 which is made of a conductive material and is embedded within the insulating film 42 and the interlayer insulating film 36.

As illustrated in FIG. 2, each reading control line 10 is disposed along upper-side regions of the pixel portions 100. Each reading control line 10 is disposed so that a part of each reading control line 10 is overlapped with the control gates 14 of the pixel portions 100. As illustrated in FIG. 8, the reading control line 10 is formed on the interlayer insulating film 36 and is electrically connected to the control gate 14 via a plug 21 which is made of a conductive material and is embedded within the insulating film 42 and the interlayer insulating film 36. The control gate 14 is formed to extend to a region above the device isolation region 32. The plug 21 and the control gate 14 are connected to each other above the device isolation region 32.

As illustrated in FIG. 2, each signal output line 12 is disposed along right-side regions of the pixel portions 100. Each signal output line 12 is disposed so that a part each signal output line 12 is overlapped with the drain regions 19b of the pixel portions 100. As illustrated in FIG. 9, the signal output line 12 is formed in the interlayer insulating film 36 and is electrically connected to the drain region 19b via a plug 23 which is made of a conductive material and is embedded within the insulating film 42.

As illustrated in FIG. 2, each ground line 13 is disposed along left-side and upper-side regions of the pixel portions 100. Each ground line 13 is disposed so that a part of each ground line 13 is overlapped with the source regions 19a of the pixel portions 100. As illustrated in FIGS. 7 and 9, the ground line 13 is formed inside the interlayer insulating film 36 and is electrically connected to the source region 19a via a plug 22 which is made of a conductive material and is embedded within the insulating film 42.

The reading control lines 10, the writing control lines 11, the signal output lines 12 and the ground lines 13 are each made of a conductive material such as aluminum.

As illustrated in FIGS. 5 to 9, a planarization film 39 is formed on an interlayer insulating film 37. The light shield film 38 for shielding, from light, regions other than a part of the photoelectric conversion section 17 of each pixel portion 100 is formed within the planarization film 39. A color filter 40 is formed on the planarization film 39, and a microlens 41 is formed on the color filter 40.

An example of an imaging operation of the solid-state imaging device configured as described above will be described below.

At an exposure start timing, the writing control voltage WCG is applied to the control gates 15 of all the pixel portions 100. Light passing through the openings of the light shield films 38 during the exposure is incident on the photoelectric conversion sections 17, which generate electric charges. The generated electric charges are moved through regions (channels) of the p well layer 31 which are overlapped with the control gates 15 and are injected into the FGs 16 through the oxide films 33 and 35 from the channels. At an exposure end timing, the application of the writing control voltage WCG to the control gates 15 of all the pixel portions 100 is stopped. Then, signals are read out for each line by the RTs 19 and the reading circuit 20. The reading signals are sequentially output from the output amplifier 60.

As described above, in the solid-state imaging device 1, the region K of the photoelectric conversion section 17 is shielded by neither the FG 16 nor the control gate 15. The light incident onto the opening of the light shield film 38 is allowed to be wholly incident onto the photoelectric conversion section 17. Therefore, degradation in light utilization efficiency can be prevented. Further, the control gate 15 is overlapped with all sides constituting the peripheral edge of the photoelectric conversion section 17. Therefore, the entire peripheral edge of the photoelectric conversion section 17 can serve as the region through which the electric charges generated in the photoelectric conversion section 17 flows out from the photoelectric conversion section 17. Accordingly, the efficiency of electric charge injection into the FG 16 can be improved, and the speed of electric charge injection into the FG 16 can be enhanced.

Furthermore, in the solid-state imaging device 1, no drain region of the WT 18 exists in the vicinity of the FG 16. Therefore, injection of a dark current from a drain region can be prevented. In particular, in the solid-state imaging device 1, the control gate 15 is overlapped with all the sides of the peripheral edge of the photoelectric conversion section 17. Therefore, if an attempt were to be made to provide a drain region for the WT 18, the drain region would have to be provided to be opposed to all the sides of the peripheral edge of the photoelectric conversion section 17, and the dark current injected from the drain region would be increased, which might degrade the S/N ratio. However, in the configuration of the present embodiment, since the source region of the WT 18 also functions as a drain region thereof, the dark current can be suppressed, to thereby improve the S/N ratio.

Furthermore, in the solid-state imaging device 1, no drain region of the WT 18 exists. Therefore, there is no need to provide any wiring for applying a voltage to a drain region. Consequently, the number of wirings can be decreased as compared with the structure described in JP 2002-280537 A, and the photoelectric conversion section 17 can be enlarged accordingly to improve sensitivity, or the photoelectric conversion section 17 can be increased in number to realize an increase in the number of pixels.

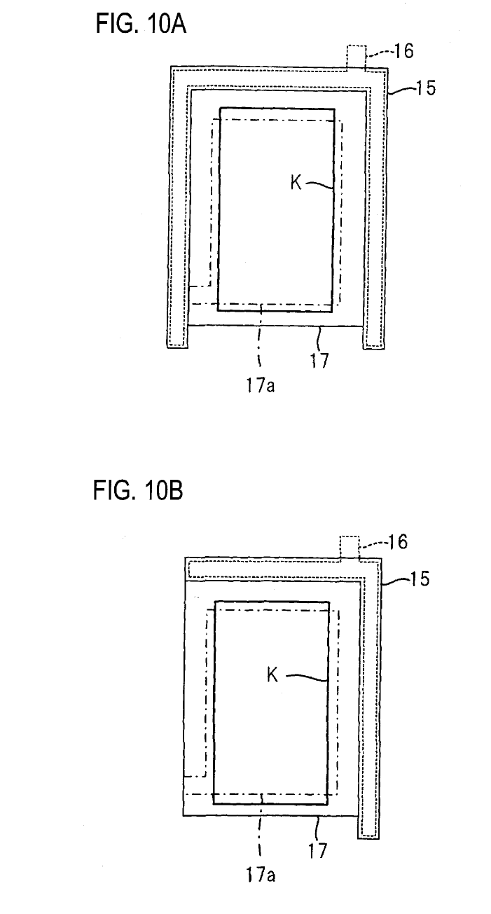

In the above embodiment, the control gate 15 is overlapped with all the sides of the peripheral edge of the photoelectric conversion section 17 in plan view. However, the present invention is not limited thereto. The control gate 15 may be overlapped with at least two of the sides of the peripheral edge of the photoelectric conversion section 17 in plan view. For example, the control gate 15 may be overlapped with three sides of the peripheral edge of the photoelectric conversion section 17 as illustrated in FIG. 10A. Alternatively, the control gate 15 may be overlapped with two sides of the peripheral edge of the photoelectric conversion section 17 as illustrated in FIG. 10B.

The control gate 15 is formed so as to be overlapped with two or more of the sides of the peripheral edge of the photoelectric conversion section 17. Thus, the region, through which the electric charges generated in the photoelectric conversion section 17 flows out from the photoelectric conversion section 17, can be increased as compared with the case where the control gate 15 is overlapped with only one side of the peripheral edge of the photoelectric conversion section 17. As a result, the efficiency of electric charge injection into the FG 16 can be improved, and the speed of electric charge injection into the FG 16 can be enhanced.

Moreover, the above description has been made on the assumption that the WT 18 has the two-terminal structure. However, the WT 18 may have a three-terminal structure as described in JP 2002-280537 A.

The above description on the embodiments of the invention has been provided for the purposes of illustration and description. It is not intended to be exhaustive or to limit the invention thereto. Various modifications will be apparent to one skilled in the art.

What is claimed is:

1. A solid-state imaging device comprising:
a photoelectric conversion section that is provided in a semiconductor substrate; and
a writing transistor including
an electric charge accumulation section that is provided above the semiconductor substrate, and
a control gate that injects electric charges generated in the photoelectric conversion section into the electric charge accumulation section, wherein
the control gate is located outside of a region, onto which light is incident, of the photoelectric conversion section in plan view, and
the control gate is overlapped with at least two sides of a peripheral edge of the photoelectric conversion section in plan view.

2. The solid-state imaging device according to claim 1, wherein the control gate is overlapped with all sides of the peripheral edge of the photoelectric conversion section in plan view.

3. The solid-state imaging device according to claim 1, further comprising:
a reading transistor that reads a signal corresponding to the electric charges injected into the electric charge accumulation section, wherein
the writing transistor has a two-terminal structure having
a source connected to the photoelectric conversion section, and
the control gate.

4. The solid-state imaging device according to claim 2, further comprising:
a reading transistor that reads a signal corresponding to the electric charges injected into the electric charge accumulation section, wherein
the writing transistor has a two-terminal structure having
a source connected to the photoelectric conversion section, and
the control gate.

5. The solid-state imaging device according to claim 1, wherein
the photoelectric conversion section is formed of a first impurity layer of a first conductivity type,
the solid-state imaging device further comprises a second impurity layer that is formed at a surface of the first impurity layer of the first conductivity type and that has a second conductivity type opposite to the first conductivity type,
a part of the second impurity layer extends to a region above a device isolation region having the second conductivity type and is connected to the device isolation region,
one part of the electric charge accumulation section located above the part of the second impurity layer and the other parts of the electric charge accumulation section are formed above the semiconductor substrate via insulating films having different thicknesses, and
the insulating film located between the one part of the electric charge accumulation section located above the part of the second impurity layer and the semiconductor substrate is thicker than the insulating film located between the other parts of the electric charge accumulation section and the semiconductor substrate.

6. The solid-state imaging device according to claim 2, wherein
the photoelectric conversion section is formed of a first impurity layer of a first conductivity type,
the solid-state imaging device further comprises a second impurity layer that is formed at a surface of the first impurity layer of the first conductivity type and that has a second conductivity type opposite to the first conductivity type,
a part of the second impurity layer extends to a region above a device isolation region having the second conductivity type and is connected to the device isolation region,
one part of the electric charge accumulation section located above the part of the second impurity layer and the other parts of the electric charge accumulation section are formed above the semiconductor substrate via insulating films having different thicknesses, and
the insulating film located between the one part of the electric charge accumulation section located above the part of the second impurity layer and the semiconductor substrate is thicker than the insulating film located between the other parts of the electric charge accumulation section and the semiconductor substrate.

7. The solid-state imaging device according to claim 3, wherein
the photoelectric conversion section is formed of a first impurity layer of a first conductivity type,
the solid-state imaging device further comprises a second impurity layer that is formed at a surface of the first impurity layer of the first conductivity type and that has a second conductivity type opposite to the first conductivity type,
a part of the second impurity layer extends to a region above a device isolation region having the second conductivity type and is connected to the device isolation region,
one part of the electric charge accumulation section located above the part of the second impurity layer and the other parts of the electric charge accumulation section are formed above the semiconductor substrate via insulating films having different thicknesses, and
the insulating film located between the one part of the electric charge accumulation section located above the part of the second impurity layer and the semiconductor substrate is thicker than the insulating film located between the other parts of the electric charge accumulation section and the semiconductor substrate.

8. The solid-state imaging device according to claim 4, wherein
the photoelectric conversion section is formed of a first impurity layer of a first conductivity type,
the solid-state imaging device further comprises a second impurity layer that is formed at a surface of the first impurity layer of the first conductivity type and that has a second conductivity type opposite to the first conductivity type,
a part of the second impurity layer extends to a region above a device isolation region having the second conductivity type and is connected to the device isolation region,
one part of the electric charge accumulation section located above the part of the second impurity layer and the other parts of the electric charge accumulation section are formed above the semiconductor substrate via insulating films having different thicknesses, and
the insulating film located between the one part of the electric charge accumulation section located above the part of the second impurity layer and the semiconductor substrate is thicker than the insulating film located between the other parts of the electric charge accumulation section and the semiconductor substrate.

9. An imaging apparatus comprising the solid-state imaging device according to claim 1.

10. An imaging apparatus comprising the solid-state imaging device according to claim 2.

11. An imaging apparatus comprising the solid-state imaging device according to claim 3.

12. An imaging apparatus comprising the solid-state imaging device according to claim 4.

13. An imaging apparatus comprising the solid-state imaging device according to claim 5.

14. An imaging apparatus comprising the solid-state imaging device according to claim 6.

15. An imaging apparatus comprising the solid-state imaging device according to claim 7.

16. An imaging apparatus comprising the solid-state imaging device according to claim 8.
